(19) United States
(12) Patent Application Publication
(10) Pub. No.: US 2023/0194580 A1
(43) Pub. Date: Jun. 22, 2023

(54) SYSTEM AND METHOD FOR MANAGEMENT OF ELECTRIC GRID

(71) Applicant: Safegrid Oy, Espoo (FI)

(72) Inventors: Jyrki PENTTONEN, Helsinki (FI); Jussi HAKUNTI, Turku (FI)

(73) Assignee: Safegrid Oy, Espoo (FI)

(21) Appl. No.: 17/795,705

(22) PCT Filed: Feb. 17, 2021
(86) PCT No.: PCT/FI2021/050109

§ 371 Date: Jul. 27, 2022

Related U.S. Application Data
(60) Provisional application No. 62/977,893, filed on Feb. 18, 2020.

(51) Int. Cl. G01R 19/25; H02J 13/00; G01R 31/08; G01R 31/52; G01R 29/08

(52) U.S. Cl. CPC G01R 19/2513; G01R 29/0871; G01R 29/0892; G01R 31/52; G01R 31/086; H02J 13/00002

(57) ABSTRACT

A system and a method for management of an electric grid. The system includes at least one monitoring server and at least one grid monitoring sensor communicably coupled to the at least one monitoring server. Herein the given grid monitoring sensor is installed to a given electrical utility pole of the electric grid. Each of the at least one grid monitoring sensor includes a magnetic sensor for measuring a time-variant magnetic field induced by current transients in the electric grid.

### TECHNICAL FIELD

The present disclosure relates generally to electric grid operations and more specifically, to methods and systems for management of an electric grid.

### BACKGROUND

Electric grids comprising a number of electrical networks that are interconnected with each other and provide electricity form producers to end- consumers have become a necessity in modern world. Almost all industries, commercial offices, domestic places etc. depend on electricity provided by the electric grids. Therefore, downtime of even a few minutes can severely hamper and negatively affect various sectors causing significant losses.

Generally, transmission lines (referred also as distribution lines) experience earth faults or high impedance faults due to various problems like, natural disasters, three falling on a power line or for example in case of cable installation breaking down. For example, when lightning strikes distribution lines, one or more distribution lines may break and touch earth’s surface leading to the high impedance fault or the induced electricity from the lighting might break some part or parts of the transmission/distribution network or grid. Generally, in order to locate fault, whenever, the fault occurs, each subsection of the electric grid is turned off one by one till time voltage or current value of the electric grid is restored to normal conditions that are prevalent in the electric grid without any fault. The subsection of the electric grid that was turned off so that normal conditions are restored, may be determined as faulty one. However, this method provides the subsection which is faulty and not the exact location of the fault in the subsection. Typically, precise positioning of the fault within the subsection may be done manually.

Recently, systems have been developed for locating and positioning of high impedance faults within the electric grid. Such systems concentrate looking at the steady state which is 50 Hz signals (AC signal). One way to detect these is to measure changes in magnetic fields caused by the AC signal with a magnetic sensor. For high impedance faults (or generally speaking any earth faults), sum current increases, which manifests itself in magnetic field seen by magnetic field sensors used. However, the magnetic field sensor works better at higher frequencies, due to induction effect. According to Faraday law, induced voltage in a coil is proportional to frequency. Hence, the 50 Hz signal comes out quite weak and is difficult to measure. Therefore, such systems cannot locate faults accurately and can only provide direction of a fault from a measurement point at best. Detection of point of fault is thus difficult for both overhead lines as well as underground cables. Particularly in case of finding a fault on power cables of the electric grid, which are underground is difficult as those cannot be visible inspected. In case of overhead lines the fault point might be in place which is difficult to reach so it might so improve method of finding point of fault is needed for the overhead lines as well. Furthermore the fault point might not be easily detected visually.

Therefore, in light of the foregoing discussion, there exists a need to overcome the aforementioned drawbacks associated with conventional fault detection and grid management systems.

### SUMMARY

The present disclosure seeks to provide a system for management of an electric grid. The present disclosure also seeks to provide a method for management of an electric grid. An aim of the present disclosure is to provide a solution that overcomes at least partially the problems encountered in prior art.

In one aspect, the present disclosure provides a system for management of an electric grid, the system comprising at least one monitoring server and at least one grid monitoring sensor communicably coupled to the at least one monitoring server, wherein a given grid monitoring sensor is installed to a given electrical utility pole of the electric grid and wherein each of the at least one grid monitoring sensor comprises a location sensor, a magnetic sensor for measuring a time-variant magnetic field induced by current transients in the electric grid.

In another aspect, the present disclosure provides a method for management of an electric grid, the method comprising
measuring a time-variant magnetic field induced by current transients in the electric grid;
processing measured time-variant magnetic field data; and
estimating fault location based on the processed time-variant magnetic field data.

Embodiments of the present disclosure substantially eliminate or at least partially address the aforementioned problems in the prior art, and enable truthful management of an electric grid.

Additional aspects, advantages, features and objects of the present disclosure would be made apparent from the drawings and the detailed description of the illustrative implementations construed in conjunction with the appended claims that follow.

It will be appreciated that features of the present disclosure are susceptible to being combined in various combinations without departing from the scope of the present disclosure as defined by the appended claims.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1 is a block diagram illustration of a system for management of an electric grid, in accordance with an embodiment of the present disclosure;

FIG. 2 is a block diagram illustration of a system for management of the electric grid, in accordance with another embodiment of the present disclosure;

FIG. 3 is a graph illustrating a waveform representing time-variant magnetic field, in accordance with an embodiment of the present disclosure;

FIGS. 4A-4C are graphs illustrating practical fault current transients in simulated environment and from measurements from real systems, in accordance with an embodiment of the present disclosure;

FIGS. 5A-5D are graphs illustrating typical waveforms acquired from a long overhead line feeder with two grid monitoring sensors, one before and another one after an earth fault location, in accordance with an embodiment of the present disclosure;

FIG. 6 is a graph illustrating magnetic field measurements obtained using a magnetic sensor with and without a ferrite coil, in accordance with an embodiment of the present disclosure; and

FIG. 7 is a flowchart listing steps of a method for monitoring the electric grid, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

In one aspect, the present disclosure provides a system for management of an electric grid, the system comprising at least one monitoring server and at least one grid monitoring sensor communicably coupled to the at least one monitoring server, wherein a given grid monitoring sensor is installed to a given electrical utility pole of the electric grid and wherein each of the at least one grid monitoring sensor comprises a location sensor, a magnetic sensor for measuring a time-variant magnetic field induced by current transients in the electric grid.

In another aspect, the present disclosure provides a method for management of an electric grid, the method comprising
measuring a time-variant magnetic field induced by current transients in the electric grid;
processing measured time-variant magnetic field data; and
estimating fault location based on the processed time-variant magnetic field data.

The present disclosure provides a system and method for management of an electric grid that enables fault detection and location in a timely and accurate manner, thereby improving performance of the electric grid and increasing service life of equipment in the electric grid. Furthermore, accurate location of faults occurring in an electric grid enables maintenance crews to reach location faster, thereby decreasing costs involved and downtime of the electric grid.

Pursuant to embodiment of the present disclosure, there is provided a system and a method for management of an electric grid. Herein, the term “electric grid” refers to an interconnected network comprising electrical substations, high voltage distribution power lines (overhead and underground cables), electrical utility poles, lower voltage distribution lines (overhead and underground), etc used to distribute electricity from electricity power stations to usage (consumers or factories etc). Notably, the system and method of the present disclosure enables detection and location of faults occurring in the electric grid and also, enable predictive maintenance of components in the electric grid. The present disclosure further enables collection of monitoring data relating to the electric grid of any network topology, overhead line, underground, compensated, isolated, resistor earthed or solidly grounded. Herein, the detection of fault comprises detection of high impedance faults, low impedance earth faults, transient or permanent as well as short circuits, load changes, trips, reconnects and so on. A term distribution line can be also referred as as a transmission lines or electrical power lines. In present disclosure terms can be used interchangeable.

It may be appreciated that an electrical fault may be a condition in electrical network which deviates the current and the voltage from their respective nominal values. An example of a faults are earth faults. As an example, a high impedance faults (sub set of earth fault) may occur in the distribution network due to a neutral to ground connection. This may take place in a number of conditions such as, but not limited to, when a distribution (overhead distribution) line comes in a contact with a tree, when the distribution line breaks and contacts the ground. Generally, the low fault currents may lie in the range of 0 to 50 A. Further more similar fault might occur if an underground distribution line is for example damaged.

The system comprises at least one monitoring server. Herein, the term “at least one monitoring server” refers to a structure and/or module that includes programmable and/or non-programmable components configured to store, process and/or share information. Specifically, the at least one monitoring server includes any arrangement of physical or virtual computational entities capable of enhancing information to perform various computational tasks. Furthermore, it should be appreciated that the at least one server may be a single hardware server and/or plurality of hardware servers operating in a parallel or distributed architecture. In an example, the at least one server may include components such as memory, at least one processor, a network adapter and the like, to store, process and/or share information with other entities, such as the at least one grid monitoring sensor.

The system further comprises at least one grid monitoring sensor. Notably, each of the at least one grid monitoring sensor comprises a location sensor and a magnetic sensor. Notably, a given grid monitoring sensor is installed to a given electrical utility pole of the electric grid. Therefore, a given grid monitoring sensor is configured to acquire information relating to the electrical utility pole and area surrounding the electrical utility pole at which the given grid monitoring sensor is installed. It will be appreciated that the electrical utility pole may comprise a current sensing means installed thereon, wherein the current sensing means is communicably coupled to the grid monitoring sensor installed on said electrical utility pole. Alternatively, optionally, the at least one grid monitoring sensor comprises the current sensing means for measuring current value of the current transmitted from the electrical utility pole. The at least one grid monitoring sensor is communicably coupled to the at least one monitoring server. In an instance, the at least one grid monitoring sensor is communicably coupled to the at least one monitoring server using a data communication network. Such data communication networks include, but are not limited to, Wide Area Networks (WANs), Metropolitan Area Networks (MANs), the Internet, radio networks (such as long range or short range such as Bluetooth, NFC WLAN), telecommunication networks (2G, 3G, 4G, 5G etc). In an implementation, the system comprises a plurality of grid monitoring sensors, wherein the at least one monitoring server is communicably coupled to each of the plurality of grid monitoring sensors using one or more data communication networks. The term utility pole is not limited to a pole for holding overhead lines, but the term might be considered in present disclosure to include a node point or other point in the distribution grid in which the mentioned sensors can be installed. For example in case of underground cables the utility pole can be for example a cabinet connecting one segment of the grid to an other segment.

The magnetic sensor measures a time-variant magnetic field induced by current transients in the electric grid. Notably, in overhead line networks, the magnetic sensor measures the magnetic field below the distribution lines of the electric grid. The magnetic sensor is placed below the distribution line conductors and includes one or more coils, which contain high permeability magnetic material. In an instance, an earth fault or a high impedance fault occurs in the electric grid, current transients or discharge transients are generated in the distribution lines. The current transients in the distribution lines induce a time-variant magnetic field that induce electromotive force in the one or more coils of the magnetic sensors. Such electromotive force may, optionally, be amplified by low noise preamplifier. It will be appreciated that the time-variant magnetic field data is acquired in form of a waveform.

As mentioned previously, the magnetic sensor comprises one or more coils. Notably, a first coil of the magnetic sensor is assembled to be in perpendicular position relative to the distribution lines to optimally pick up the magnetic field induced by sum current of the distribution line conductors. Additionally, a second coil may be placed orthogonally at a 90-degree angle, pointing towards the distribution line conductors. With such orthogonal placement of the coil, phase currents in the distribution line conductors can be determined in addition to the sum current thereof. Specifically, determination of the phase currents from the two orthogonal magnetic field measurements, Hₓ and H_{z} is done by expressing phase currents I₁, I₂ and I₃ causing the magnetic fields Hₓ and H_{z} by a linear relation as 3x2 matrix A, for instance as

$$\left(\begin{matrix}{\text{H}}_{\text{x}} \\ {\text{H}}_{\text{z}}\end{matrix}\right) = \left(\begin{matrix}{\text{A}}_{11} & {\text{A}}_{12} & {\text{A}}_{13} \\ {\text{A}}_{21} & {\text{A}}_{22} & {\text{A}}_{23}\end{matrix}\right) \left(\begin{matrix}{\text{I}}_{1} \\ {\text{I}}_{2} \\ {\text{I}}_{3}\end{matrix}\right)$$

The matrix A depends on geometry, for example, on the distance of the second coil to the conductors (h) and distance between the conductors (d). In a delta connected network, the sum of the phase currents equates to zero. Therefore, the phase currents can be represented by two independent currents, say, I₁ and I₂. Thus, there is a 2x3 matrix, which maps Hₓ and H_{z} measurement to phase currents I₁, I₂ and I₃. The retrieved phase currents can be used to, for example, monitor the power quality delivered in the grid.

It will be appreciated that the time-variant magnetic field induced by current transients in distribution line conductors is directly proportional to the current transients, but induced voltages are proportional to the frequency by Faraday law. Therefore, when the 50 Hz is measured, the voltages induced to the coil of the magnetic sensor are substantially smaller, than, for example, when measuring fast transients. Therefore, the magnetic sensor has a multi-scape (scale - or range) preamplifier stage so that several data channels are provided to the CPU. For example, a low pass filter (<1 kHz) and high gain for the 50 Hz and associated harmonics, or a high pass filter (>1 kHz) and lower gain for measuring the current transients. Such multi-range method of data acquisition is optimal way to harvest all information from the magnetic sensor.

Optionally, the location sensor is configured to timestamp current values transmitted from the electrical utility pole. Notably, timestamp of each pulse of current transmitted from the electrical utility pole is recorded. Additionally, the at least one grid monitoring sensor is configured to store current value and voltage value of each of pulse of current transmitted corresponding to the timestamp thereof. The location sensor is configured to acquire accurate timing information, wherein accuracy of such timing information is in a range of 600 to 700 nanoseconds. Additionally, optionally, the location sensor is configured to communicate location of the electrical utility pole to the at least one monitoring server.

Optionally, the at least one grid monitoring sensor is configured to measure different physical configurations of electrical utility poles. The physical configuration of the electrical utility pole includes, but is not limited to, layout of distribution line conductors (for example, horizontal, vertical), phase separation, measurements in different materials of pole (for example, wooden, fiberglass, steel, concrete), two or more circuits in the same electrical utility pole, two D primaries, sub-transmission.

Optionally, a given grid monitoring sensor installed to a given electrical utility pole is configured to
measure electric field induced by electrical power lines in the electric grid;
measure one or more parameters relating to operational characteristics of the given electrical utility pole;
preprocess measured data relating to the electric grid for filtering the measured data; and
communicate the preprocessed measured data to the at least one monitoring server.

Optionally, in this regard, the one or more parameters relating to operational characteristics of the given electrical utility pole refers to parameters that may influence operation of the given electrical pole and/or may cause a fault in the operation thereof. Such one or more parameters may include, but are not limited to, temperature of the distribution lines, ambient temperature around the electrical utility pole, windspeed around the electrical utility pole, humidity around the electrical utility pole. Consequently, the given grid monitoring sensor includes one or more sensors for measuring the one or more parameters relating to the operational characteristics of the given electrical utility pole. Notably, the measured data relating to the electric grid, specifically, the time-variant magnetic field data, measured electric field and measured one or more parameters are pre-processed for filtering thereof. Specifically, the measured data is analyzed using heuristic algorithms. Notably, the heuristic algorithms analyze the measured data to determine any deviation or anomaly from standard operating conditions of the electric grid. In an instance, the measured data does not indicate any deviation, the data may be filtered and not communicated to the at least one monitoring server. Beneficially, such filtering at the at least one grid monitoring sensor significantly reduces computational time (and communication bandwidth) and effort of the at least one monitoring server. Furthermore, the measured data may be analyzed to determine any insights or conclusions therefrom that may be subsequently communicated to the at least one monitoring server. It will be appreciated that the at least one grid monitoring sensor may include comprises programmable components configured to process information received from the location sensor, the magnetic sensor and the one or more sensors for measuring the one or more parameters.

Optionally, the at least one monitoring server is configured to classify time-variant magnetic field data using machine learning algorithms. Notably, the at least one monitoring server receives data from the magnetic sensor for event associated with the electric grid, for example an earth fault. The at least one monitoring server classifies the waveform data using unsupervised learning methods. Notably, high-frequency (for example, 1 Megahertz) sampling triggers filtering at the at least one grid monitoring sensor, wherein only relevant information is sent to the at least one monitoring server from the at least one grid monitoring sensor. Notably, the at least one grid monitoring sensor employs a library of heuristically determined feature extraction algorithms, that produce feature vector from each acquired data stream of time-variant magnetic field. Herein, selection of the features requires deep understanding on the domain, for example of electrical grid dynamics, model of the grid and the like. Notably, unsupervised learning algorithm, such as K-means algorithm, clusters the time-variant magnetic field data automatically into classes, such as different types of faults, load changes, disturbances, anomalies etc. In other words, unsupervised learning algorithms are employed to classify or cluster the large data sets produced (in order of millions of records) from the at least one grid monitoring sensor. Therefore, the time-variant magnetic field data may be classified based on human understandable elements such as high impedance transient earth fault, high impedance permanent earth fault, high impedance intermittent earth fault, low impedance, permanent short circuit, load change, asymmetry and so forth. Therefore, the at least one monitoring server adapts to different scenarios without any requirement of specific configuration or programming. Beneficially, the system can be employed in different network topologies without requiring reprogramming.

In an example, the magnetic sensor may be situated 1 meter below the distribution line conductors, wherein the time-variant magnetic field may be 0.5 µT (micro-Tesla) for a current value of 1 Ampere. The magnetic sensor may employ ferrite coils that may increase value of the time-variant magnetic field by up to 5 times depending on configuration of the conductors and the magnetic sensors. Notably, with 500 turns in the ferrite coil and an area of 2 cm * 2 cm, voltage induced in the coil is 5*10⁻⁷*(dI/dt), wherein I is the current value. Therefore, for current value of 1A at 50 Hertz, voltage indued in the coil is 0.2 millivolts. Therefore, a 50 Hertz current can be measured within a resolution of 1 Ampere with a magnetic sensor 1 meter below the distribution line conductors. In another example, for overheard line voltage of 20 kilovolts positioned at 10 meters above the ground, electric field values 1 meter and 3 meter below the ground are 2.3 kilovolt/meter and 0.7 kilovolt/meter. Such voltage values may be measured using conventional capacitive sensors.

Optionally, the at least one monitoring server is configured to
process measured time-variant magnetic field data from the at least one grid monitoring sensor;
estimate fault location based on the processed time-variant magnetic field data.

Optionally, in this regard, the at least one grid monitoring sensor is configured to measure distribution line currents and enables measurements in different physical configuration of the phases in a pole. Notably, distribution feeders are modelled as distributed capacitance and inductance network. It is to be noted that in a high impedance fault or an earth fault, current transients occur and energy in the distribution line to earth distributed capacitances dissipates via fault location. When an earth fault occurs, current transients are generated, of which the time-variant magnetic field is measured by the magnetic sensor of the at least one grid monitoring sensor. The waveform of time-variant magnetic field has a unique fingerprint, wherein the characteristics of the waveform are derived from the modelling of the dynamics of medium voltage feeder network. Notably, duration of the initial part of the current transient is in a range of 30-100 microseconds, dependent on the network topology. Therefore, in order for high quality analysis of the pulse, sampling needs to take place one order of magnitude faster, than are the highest characteristic frequencies. In an example, 1 million samples per second may be required for such sampling. The magnetic sensor of the at least one grid monitoring sensor is capable of providing such high sampling data in comparison to conventional protection relays and fault indicators, which typically have only a few k samples/second.

Optionally, in an instance when the high impedance fault event is recognized, sampled data of current measurements and the time-variant magnetic field data are sent to at least one monitoring server with an accurate timestamp from the location sensor. In an embodiment, the at least one monitoring server is configured to correlate measurements from a number of different grid monitoring sensors taking into consideration the timestamp information and measured data about medium voltage cable propagation speeds (for example 150 meter per microsecond in underground cables, and 300 meter per microsecond in overhead lines). The correlation analysis takes into consideration information about modelling the nature of the current transients. The transients have a certain fingerprint and this information makes it possible to enhance the accuracy of cross correlation of the signals. As a result of an estimation of the fault location is derived, with error bounds. In an example, when two grid monitoring sensors are located 5 km from each other, the propagation speed is may approximately be 300 meters per microsecond and timestamp accuracy is 600 ns, fault location error bounds are less than 100 meters. Thus, based on this analysis the at least one monitoring server is configured to show in a map a circle for estimate fault location with a radius of 50 meters.

It will be appreciated that in many instances, more than two grid monitoring sensors report the same earth fault. In an example of a feeder, where the grid monitoring sensors are installed at electrical utility poles distanced at 5 kilometers from each other and each of the four grid monitoring sensors reports an occurred earth fault signal. The inter-distance matrix in an instance no earth fault has occurred may be

| | Site 1 | Site 2 | Site 3 | Site 4 |
|---|---|---|---|---|
| Site 1 | X | 5 | 10 | 15 |
| Site 2 | 5 | X | 5 | 10 |
| Site 3 | 10 | 5 | X | 5 |
| Site 4 | 15 | 10 | 5 | X |

In an instance an earth fault occurs between sites 3 and 4, specifically, 1 km from site 3. We calculate ΔX_{AB} = |ν(t_{A}- t_{B})|, wherein v is velocity of the current and (t_{A}-t_{B}) is time taken for a given current pulse to travels between electrical utility poles A and B. The inter-distance matrix in such instance may be

| | Site 1 | Site 2 | Site 3 | Site 4 |
|---|---|---|---|---|
| Site 1 | X | 5 | 10 | 7 |
| Site 2 | 5 | X | 5 | 2 |
| Site 3 | 10 | 5 | X | 3 |
| Site 4 | 7 | 2 | 3 | X |

Herein, measurements for ‘Site 4’ in corresponding row and column there to and therefore, the fault can be detected as between site 3 and 4 by comparing the inter-distance matrices of two aforementioned instances. Notably, employing information from a higher number of grid monitoring sensors may further improve accuracy of the fault location.

Optionally, another use of the inter-distance matrix, and the sensor data acquired from multiple grid monitoring sensors (preferably, more than two) is that it enables pinpointing fault location in grid topology. Notably, in a medium voltage grid, disconnectors may be remotely controlled and a status of a switch may not be communicated to the at least one monitoring server. Therefore, the at least one monitoring server may not have information relating to paths between the sensors and exact pinpointing of fault location Such accuracy may be achieved because when more than two sensors detect an event, inter-distance matrix is created and this provides unique identification of the paths between the sensors and therefore fault location can be uniquely pinpointed.

Optionally, the at least one monitoring server is configured to cluster time-variant magnetic data obtained in a given timeframe to generate a meta-event, indicating a group of events that may likely be associated with a single cause. Subsequently, the at least one monitoring server analyzes high speed (1 Megahertz) waveform using adaptive wavelet correlation and synchronization algorithms to accurately align timings of the group of events. Using such methodology, fault and other anomalies in the electric grid can be located with an error bound of few tens of meters. It will be appreciated that a waveform measured at 1 kilometer away from the fault location may significantly differ from the waveform measured at 10 kilometers away from the fault location, despite originating from the same fault. The present disclosure employs deep understanding and modelling of grid dynamics and wavelet-based synchronization of incoming current pulse to identify a correlation between different waveform and identify fault location thereby.

Optionally, the at least one monitoring server is configured to provide monitoring data relating to the electric grid to at least one grid application server. Herein, monitoring data relating to the electric grid may be the preprocessed measured data obtained by preprocessing measured data using the at least one grid monitoring sensor. The grid application server may be a server connecting grid application operators. The grid application operators may employ monitoring data for a distribution management system (DMS), fleet management, planning and the like. It will be appreciated that the distribution management system (DMS) may be a set of applications configured to monitor and control an entire electrical distribution system efficiently in order to minimize outage time and maintain acceptable frequency and voltage levels. The fleet management may also refer to management of a group of electrical networks and electric grids. A data interface may transfer the monitoring data from the at least one monitoring server to multiple grid application servers such as, DMS, fleet management, planning, etc. of grid application operators. According to alternative or additional embodiment a given grid monitoring sensor has a buffer memory, which a size of the buffer memory is configured to be a function length of associated electrical power line of the grid. This way an amount of monitoring data which is collected in the given grid monitoring sensor can be limited based on length of distribution line(s) (electrical power line(s)) connected to said point of monitoring. In deed this enables to limit amount of data needed to collect and to provide to monitoring server thus making data communication more efficient. As an example if length of distribution line from the monitoring server is 1 km then maximum time a fault signal can reach to the sensor is 1 km/c (in which c is speed of light) = 3.3 micro seconds i.e. in case of not detecting any faults data can be removed after 3.3 microseconds. If the electrical power line length is for example 10 km then at least 33 micro seconds of measurement data must be stored. Further advance of this configurable buffer memory is that it can be used to reduce need of memory size in the sensors. This way the sensors, which are installed in a part of the grid having short electrical power line segments can have smaller memory, than those sensors which are installed in a part of the grid having long electrical power lines. Further more selected communication method can be selected to based on size of the buffer memory. (large memory might require faster communication than a smaller memory to enable communication of results to reach servers at same time).

Optionally, the estimated fault location may be sent to grid application server connected via the data interface to the at least one monitoring server, for example, to DMS for automatic fault location isolation restoration (FLIR) operations, for example, using the fault location information to instigate the FLIR operations in the DMS and therefore, perform fully automatic fault isolation via remotely operated disconnectors. It will be appreciated that depending on the estimated fault location, the FLIR may locate the fault by isolating each conductor such, as, each overhead grid line, in the estimated fault location one by one. The electricity to the isolated conductor may be turned off. If by blocking electricity to the isolated conductor, the current in the electric grid returns to normal conditions, then the isolated conductor may be faulty one. Otherwise, the isolated conductor may not be fault and the current may be restored in it.

Optionally, the at least one monitoring server is further configured to analyze the monitoring data relating to the electric grid using statistical inference algorithms to determine an operational condition of the electric grid and predict maintenance likelihood thereof. Herein, the operational condition may be defined as a condition of the overhead wire and the distribution lines and a value of a leaking current. Furthermore, maintenance likelihood refers to a maintenance of the electric grid components that may be required in future. Notably, big data statistical information may be collected from the at least one monitoring server and statistical inference algorithms may be executed to determine the condition of the distribution grid and to enabling predictive maintenance likelihood.

It will be appreciated that the at least one grid monitoring sensor are sensitive and have high sampling frequency. Hence, they may be also used to pick partial discharge signals, which are often precursor events for insulation or cable failing or any other part failing. Furthermore, in some cases it is critical to get information about the occurrence of earth faults, permanent or transient to the operational crew in the field so, that further damages could be avoided. For example, in dry season, conductor touching a tree even momentarily, might cause forest fire. In such cases, the at least one grid monitoring sensor may detect these situations and alerts may be given immediately to crew to be dispatched in order to make sure that the fire does not escalate further. This can be automized by direct integration to dispatch system. Therefore, when the alert information provided by the at least one monitoring server is provided to crew dispatch center, any electrically induced fire may be prevented.

In an embodiment, the at least one monitoring server is, for example, a cloud server. Herein, the at least one monitoring server comprises a big data engine and enables a standalone operation. For example, the monitoring data is gathered into the big data engine of the at least one monitoring server, where the monitoring data can be analyzed and visualized locally. The at least one monitoring server further comprises a database. Herein, a data of the database may be made available to other applications such as Scada, DMS, fleet management or CRM via a data interface API. Moreover, the at least one monitoring server is equipped with an additional separate server, which provides information securely via DNP3 to Scada, to be further passed along to the DMS.

Optionally, the system further comprises a database arrangement configured to store at least one of monitoring data relating to the electric grid, operational condition of the electric grid. It may be appreciated that, the database arrangement may store a set of data in an organized manner and may be accessed by various ways. Herein, the database arrangement may store at least one of the monitoring data relating to the electric grid and the operational condition of the electric grid.

Optionally, the at least one monitoring server is configured to regenerate network topology of the electric grid based on non-fault events to estimate fault location in the electric grid. It may be noted that the at least one monitoring server may use known network topology information about the electric grid to determine the location exactly by following the route the grid lines have in the electric grid. Notably, from time to time in electric grid, such as, distribution grids there are non-fault events detected by many sensors, such as, the ones caused by voltage spikes in high voltage electric grid, tripping feeders etc. These non-faults events may be used to determine the switching state of the distribution network. This is, typically, a problem in many fault indication systems, as the information, whether disconnectors along the grid lines are on or off may not be known and usually, this is needed for calculating the exact route of the signals which in turn is needed for accurate location of faults. Additionally, these non-fault events may be also used to automatically determine the network topology of the electric grid. For example, in an embodiment, first there is a voltage spike at a primary substation level, which causes current pulses all around feeder network below it. Most at least one grid monitoring sensor may record it with accurate timestamp and may report them to the at least one grid application server. The at least one monitoring server may then perform correlation analysis and based on time differences it may, then, determine the time differences in propagation delays between the at least one grid monitoring sensor.

Optionally, the at least one grid monitoring sensor may be further configured to use the naturally occurring non-fault events as calibration points, for example, feeder tripping causes an event detected by the at least one grid monitoring sensor, which by correlating this known event by separate at least one grid monitoring sensor provides more effective calibration information. The at least one grid monitoring sensor may be further configured to filter events. It may be appreciated that medium voltage grid lines may contain events caused, for example, by loads behind the distribution transformers, trips, reconnections, glitches etc.

Optionally, the at least one grid monitoring sensor comprises a current sensing means. The sensing of the current may be performed by using the current sensing means of the at least one grid monitoring sensor, for example, by ferrite coil, wherein a resonant frequency of the at least one grid monitoring sensor is well above Nyquist frequency of input sampling frequency of sensor analog front end. In an embodiment, this is an optimal configuration, since the measurement arrangement guarantees higher gain in the higher frequencies, which in turn is beneficial for good reception of the discharge transient.

In an embodiment the at least one monitoring server is integrated into a system of electric grid operator such as, electric companies to provide monitoring data thereto.

The present description also relates to the method for management of the electric grid as described above. The various embodiments and variants disclosed above apply mutatis mutandis to the method for management of the electric grid.

Optionally, the method further comprises measuring electric field induced by electrical power lines in the electric grid, measuring one or more parameters relating to operational characteristics of a given electrical utility pole in the electric grid and pre-processing measured data relating to the electric grid for filtering the measured data.

Optionally, the method further comprises providing monitoring data relating to the electric grid to at least one grid application server.

Optionally, the method further comprises analyzing monitoring data relating to the electric grid using statistical inference algorithms to determine an operational condition of the electric grid and predict maintenance likelihood thereof.

Optionally, the method further comprises timestamping current values transmitted from an electrical utility pole in the electric grid.

Optionally, the method further comprises regenerating network topology of the electric grid based on non-fault events to estimate the fault location in the electric grid.

### DETAILED DESCRIPTION OF THE DRAWINGS

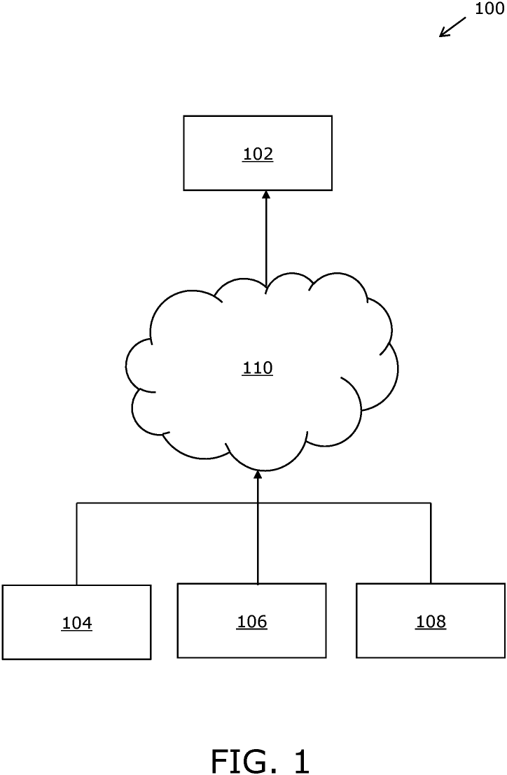

Referring to FIG. 1, there is shown a block diagram illustration of a system 100 for management of an electric grid, in accordance with an embodiment of the present disclosure. The system 100 comprising at least one monitoring server, such as the monitoring server 102 and at least one grid monitoring sensor, such as the grid monitoring sensors 104, 106, 108 communicably coupled to the at least one monitoring server 102 using a data communication network 110. Notably, a given grid monitoring sensor, such as the grid monitoring sensors 104, 106, 108 is installed to a given electrical utility pole of the electric grid. Each of the at least one grid monitoring sensor, such as the grid monitoring sensors 104, 106, 108 comprises a location sensor, a magnetic sensor for measuring a time-variant magnetic field induced by current transients in the electric grid.

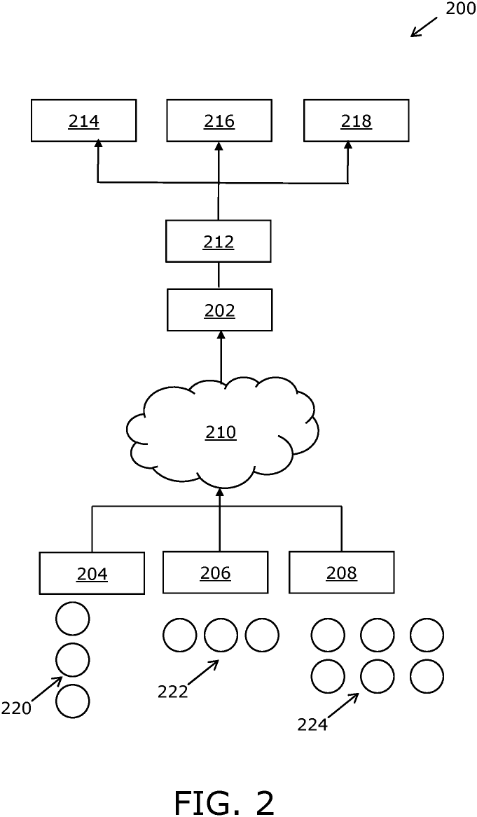

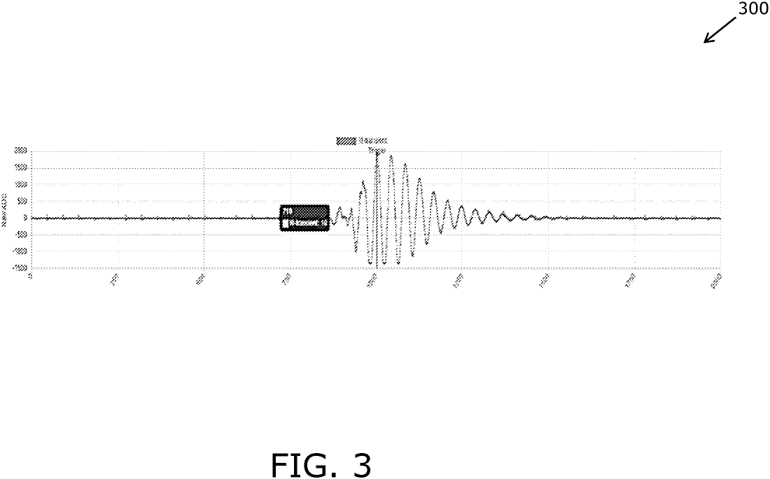

Referring to FIG. 2, there is shown a block diagram illustration of a system 200 for management of the electric grid, in accordance with another embodiment of the present disclosure. The system 200 comprises a monitoring server 202, the first grid monitoring sensor 204, the second grid monitoring sensor 206, and the third grid monitoring sensor 208. Herein, the grid monitoring sensors 204, 206 and 208 are connected over the data communication network 210 to the monitoring server 202. The system 200 further comprises a data interface 212 for transferring a monitoring data from the monitoring server 202 to one or more grid application servers. As shown in FIG. 3, the system comprises three grid application servers such as a distribution Management System (DMS) server 214, a fleet management server 216 and a planning server 218. It may be observed from the FIG. 2 that the first grid monitoring sensor 204 is installed to the pole having vertical conductors’ layout arrangement 220, the second grid monitoring sensor 206 is installed to the pole having horizontal conductors’ layout arrangement 222 and the third grid monitoring sensor 208 is installed to the pole having two horizontal circuits on top of each other with same direction 224.

Referring to FIG. 3, there is shown a graph 300 illustrating a waveform representing time-variant magnetic field, in accordance with an embodiment of the present disclosure. The monitoring server (such as the monitoring server 102 of FIG. 1) is configured to estimate fault location by processing data from the waveform representing time-variant magnetic field, wherein the X-axis of the graph 300 represents time and Y-axis of the graph 300 represents the magnetic field.

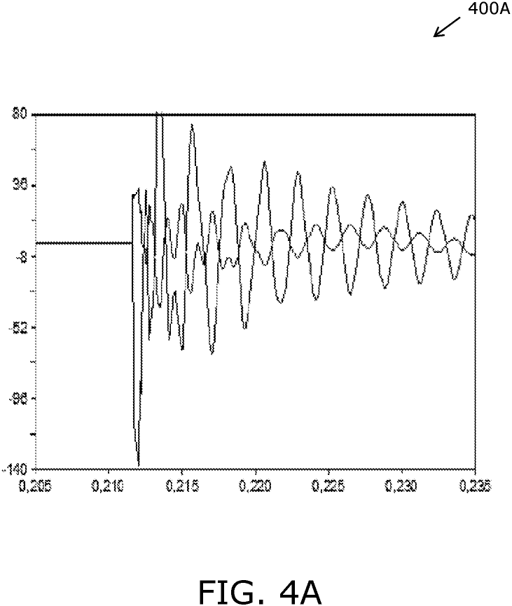

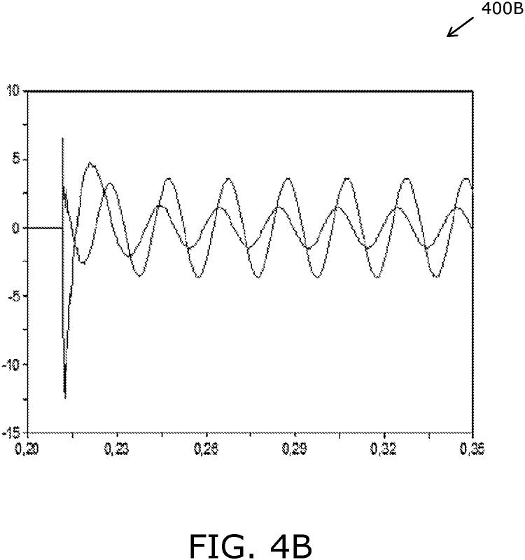

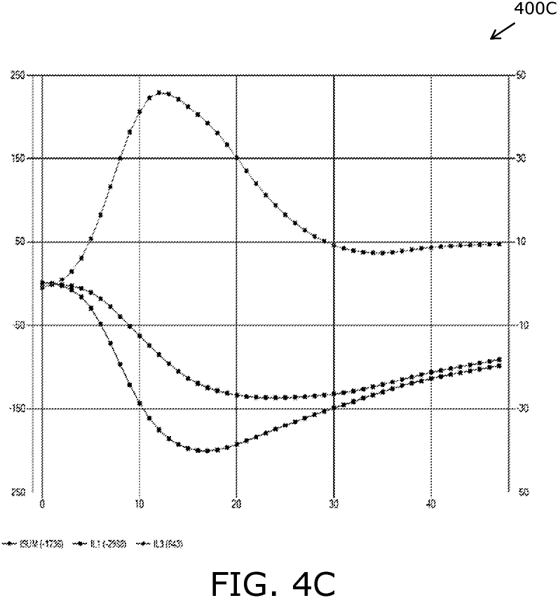

Referring to FIGS. 4A-4C, there are shown graphs 400A-400C illustrating practical fault current transients in simulated environment and from measurements from real systems, in accordance with an embodiment of the present disclosure. The graphs 400A and 400B shown in FIG. 4A and FIG. 4B respectively depict waveforms of simulated current transients. Herein, the waveform with a smaller amplitude illustrates discharge transients after the fault location and the wave form with a bigger amplitude illustrates current transients before the fault. The graph 400C of the FIG. 4C depicts the wave forms of actual measured values of the fault discharge transient.

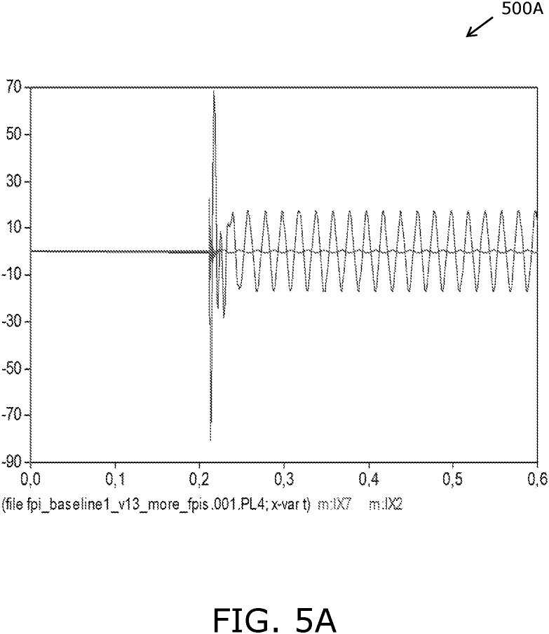

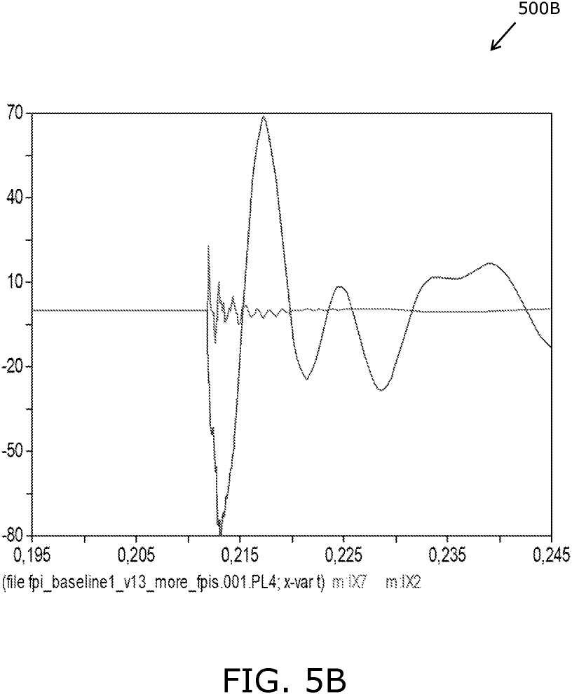

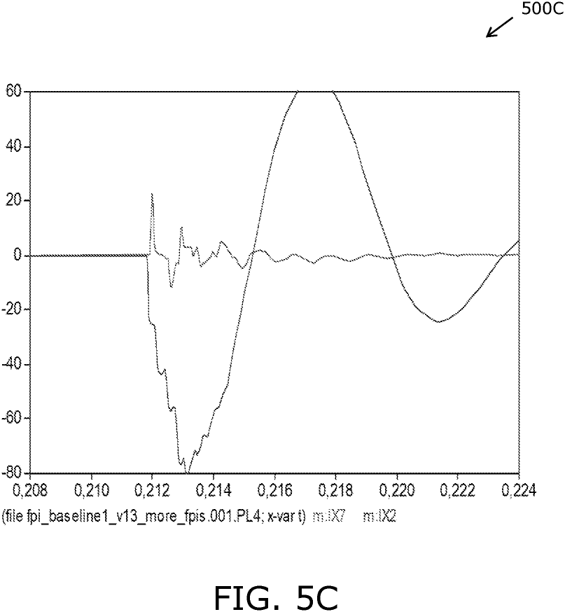

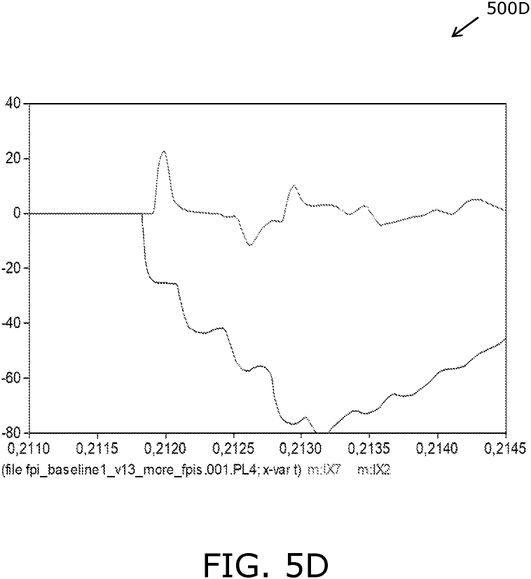

Referring to FIGS. 5A-5D, there are shown graphs 500A-500G illustrating typical waveforms acquired from a long overhead line feeder with two grid monitoring sensors, one before and another one after an earth fault location, in accordance with an embodiment of the present disclosure. The change in magnetic field when the earth fault occurs may be observed from the FIGS. 5A-5G.

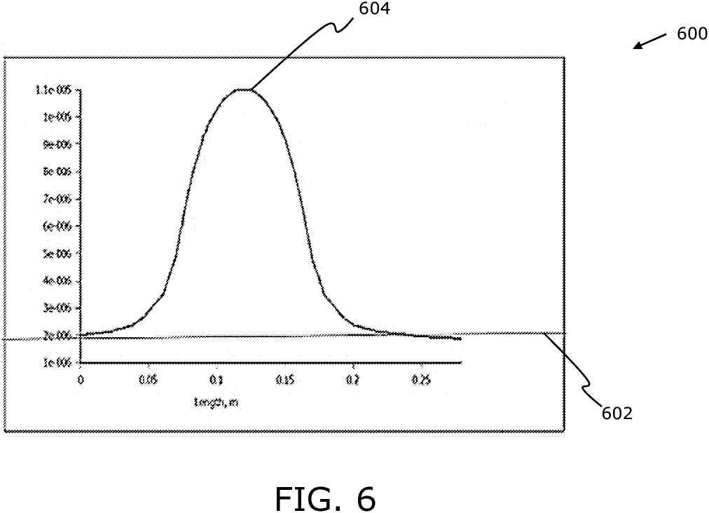

Referring to FIG. 6, there is shown a graph 600 illustrating magnetic field measurements obtained using a magnetic sensor with and without a ferrite coil, in accordance with an embodiment of the present disclosure. The line 602 illustrates the magnetic field measured using a magnetic sensor without the ferrite coil. The line 604 illustrates the magnetic field measured using a magnetic sensor with the ferrite coil.

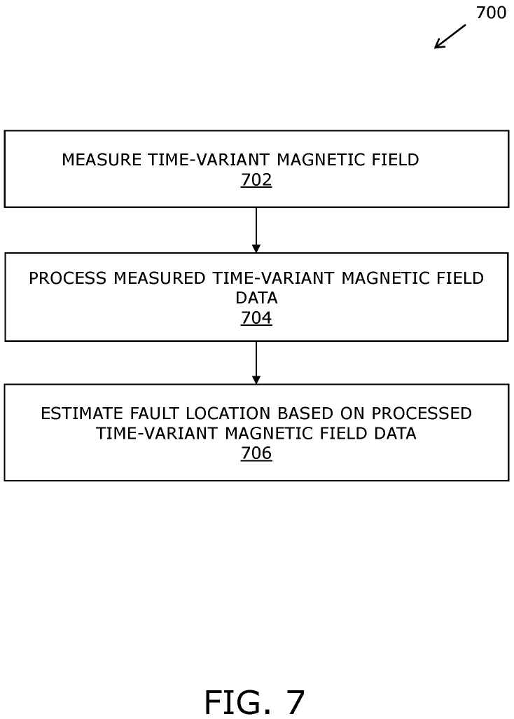

Referring to FIG. 7 there is shown a flowchart 700 depicting steps of a method for management of an electric grid, in accordance with an embodiment of the present disclosure. At a step 702, the time-variant magnetic field is measured. Herein, the time-variant magnetic field is induced by current transients in the electric grid. At a step 704, measured time-variant magnetic field data is processed. At a step 706, fault location is estimated based on the processed time-variant magnetic field data.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural.

1. A system for management of an electric grid, the system comprising at least one monitoring server and at least one grid monitoring sensor communicably coupled to the at least one monitoring server, wherein a given grid monitoring sensor is installed to a given electrical utility pole of the electric grid and wherein each of the at least one grid monitoring sensor comprises a magnetic sensor for measuring a time-variant magnetic field induced by current transients in the electric grid, wherein the at least one monitoring server is configured to receive monitoring data from the at least one grid monitoring sensor on events associated with the electrical grid, the monitoring data comprising the measured data obtained by using the at least one grid monitoring sensor, and regenerate network topology of the electric grid based on fault or non-fault events detected by the at least one grid monitoring sensor.

2-15. (canceled)

16. The system according to claim 1, wherein the non-fault events are used to determine the switching states of disconnectors along the grid lines of the electric grid to determine whether the disconnectors along the grid lines are on or off.

17. The system according to claim 1, wherein the at least one monitoring server is configured to determine time differences in propagation delays between the at least one grid monitoring sensor.

18. The system according to claim 1, wherein the at least one monitoring server is configured to use the network topology information about the electric grid to determine the location by following the route the grid lines have in the electric grid.

19. The system according to claim 1, wherein, the at least one grid monitoring sensor is configured to use the non-fault events as calibration points.

20. The system according to claim 1, wherein said non-fault events are caused by voltage spikes.

21. The system according to claim 1, wherein a given grid monitoring sensor installed to a given electrical utility pole is configured to:
measure electric field induced by electrical power lines in the electric grid;
measure one or more parameters relating to operational characteristics of the given electrical utility pole;
preprocess measured data relating to the electric grid for filtering the measured data; and
communicate the preprocessed measured data to the at least one monitoring server.

22. The system according to claim 1, wherein the at least one monitoring server is configured to:
process measured time-variant magnetic field data from the at least one grid monitoring sensor; and
estimate fault location based on the processed time-variant magnetic field data.

23. The system according to claim 1, wherein the at least one monitoring server is configured to provide monitoring data relating to the electric grid to at least one grid application server.

24. The system according to claim 1, wherein the at least one monitoring server is further configured to analyze monitoring data relating to the electric grid using statistical inference algorithms to determine an operational condition of the electric grid and predict maintenance likelihood thereof.

25. A method for management of an electric grid using the system according to claim 1, the method comprising:
measuring a time-variant magnetic field induced by current transients in the electric grid;
processing measured time-variant magnetic field data; and
estimating fault location based on the processed time-variant magnetic field data.

26. The method according to claim 25, wherein the method comprises:
receiving monitoring data for events associated with the electric grid; and
determining, based on the non-fault events, the switching states of disconnectors along the grid lines of the electric grid.

27. The method according to claim 25, wherein the method comprises detecting the non-fault events by using at least one grid monitoring sensor and communicating them to the at least one monitoring server.

28. The method according to claim 25, wherein the method comprises determining time differences in propagation delays between the at least one grid monitoring sensor.

29. The method according to claim 25, wherein the method comprises using the network topology information about the electric grid to determine the location by following the route the grid lines have in the electric grid.
